(19) United States
(12) Patent Application Publication
(10) Pub. No.: US 2026/0073083 A1
(43) Pub. Date: Mar. 12, 2026

(54) METHOD OF SETTING SEA BRIDGE POSITION

(71) Applicant: POSTECH RESEARCH AND BUSINESS DEVELOPMENT FOUNDATION, Pohang-si (KR)

(72) Inventors: Hee Kap AHN, Pohang-si (KR); Tae Kang EOM, Pohang-si (KR); Tae Hoon AHN, Pohang-si (KR); Min Ju SONG, Pohang-si (KR)

(21) Appl. No.: 18/963,934

(22) Filed: Nov. 29, 2024

(30) Foreign Application Priority Data
Sep. 6, 2024 (KR) 10-2024-0121617

(51) Int. Cl. G06F 30/13

(52) U.S. Cl. CPC G06F 30/13

(57) ABSTRACT

Disclosed herein is a method of setting a sea bridge position, which installs a sea bridge crossing the sea between two places on the same land in a straight line, thereby minimizing a travel distance on the land between the two places on the same land. The method of setting a sea bridge position includes a preprocessing operation, an operation of determining whether reduction of a maximum travel distance is possible; and an operation of reducing a possible area range of a bridge position.

### CROSS-REFERENCE TO RELATED APPLICATION

This application claims priority to and the benefit of Korean Patent Application No. 10-2024-0121617 filed on Sep. 6, 2024, the disclosure of which is incorporated herein by reference in its entirety.

### BACKGROUND

### 1. Field of the Invention

The present invention relates to a method of setting a sea bridge position, and more particularly, to a method of setting a sea bridge position, which installs a sea bridge crossing the sea between two places on the same land in a straight line, thereby minimizing a travel distance on the land between the two places.

### 2. Discussion of Related Art

A problem of setting a sea bridge position is a problem of determining an optimal arrangement place for a bridge crossing the sea so as to reduce a travel distance.

Since obstacles such as buildings and mountains exist together in the land, it is not possible to use only straight road traffic networks. Thus, when there is no suitable straight road, there is a case in which a detour should be taken.

When a sea bridge across the sea is built at an optimal location, a road traffic network can be designed to reduce a travel distance compared to traveling through land roads, and the sea bridge can also serve as a stepping stone to reduce traffic congestion and enable smooth transportation of logistics.

FIG. 1 shows a discrete two-dimensional polygon used in an algorithm for finding a location of a bridge between an island and the land.

Referring to FIG. 1, when a bridge is installed between a point a on the land and a point b on an island, it is known that an algorithm for building a bridge between discrete two-dimensional polygon is effective.

However, no algorithm is known yet to find an optimal location of a bridge across the sea without passing through other places at two points on the same land, thereby minimizing a travel distance on the land.

### RELATED ART DOCUMENT

### Non-Patent Document

Jongmin Choi, Sergio Cabello, and Hee-Kap Ahn. “Maximizing dominance in the plane and its applications.” Algorithm mica 83.11 (2021): 3491-3513.

### SUMMARY OF THE INVENTION

The present invention is directed to providing a method of setting a sea bridge position, which installs a sea bridge crossing the sea between two places on the same land in a straight line, thereby minimizing a travel distance on the land between the two places on the same land.

The technical problems to be solved by the present invention are not limited to the above-mentioned technical problems and other technical problems which are not mentioned can be clearly understood by those skilled in the art to which the present invention pertains from the following description.

According to an aspect of the present invention, there is provided a method of setting a sea bridge position, which includes a preprocessing operation, an operation of determining whether reduction of a maximum travel distance is possible, and an operation of reducing a possible area range of a bridge position.

The preprocessing may include segmenting an x-monotonic polygon chain (hereinafter, referred to as a polygonal chain) corresponding to a given coastal boundary into trapezoids using horizontal line segments and generating a range minimum/maximum query data.

The determining of whether the maximum travel distance is reduced may include determining whether a maximum travel distance on the land is reduced by constructing a bridge on the polygonal chain by determining whether a useful bridge capable of reducing the maximum travel distance is present.

The reducing of the possible area range of the bridge position may include narrowing down an area where the useful bridge is placed through a binary search inside a pocket which is an area where the useful bridge is located, and reducing a possible area range of a bridge position by comparing a first maximum travel distance and a second maximum travel distance, which are determined on the basis of whether an optimal bridge is located above or below a reference bridge inside the pocket.

When the useful bridge is present, a common reflex vertex (hereinafter, referred to as an anchor) passing through which all paths with a maximum travel distance between two arbitrary points included in the polygonal chain is present.

The technical problems to be solved by the present invention are not limited to the above-mentioned technical problems and other technical problems which are not mentioned can be clearly understood by those skilled in the art to which the present invention pertains from the following description.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a diagram illustrating a discrete two-dimensional polygon used in an algorithm for finding a location of a bridge between an island and the land;

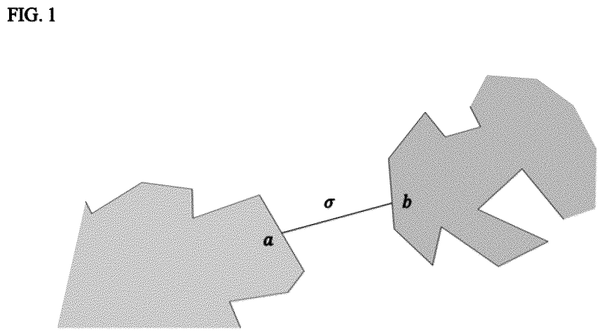

FIG. 2 is a diagram illustrating a discrete two-dimensional polygon used in an algorithm for finding a location of a bridge on the same land according to the present invention;

FIG. 3 is a flowchart illustrating a method of setting a sea bridge position according to the present invention;

FIG. 4 is a diagram illustrating operation of segmenting a trapezoid shape;

FIG. 5 is a diagram illustrating a relationship between a reflex vertex and an anchor of a chain P;

FIG. 6 is a diagram illustrating a maximum travel path and an anchor when a bridge capable of reducing a maximum travel distance is present;

FIG. 7 is a diagram illustrating an example of a pocket;

FIG. 8 is a diagram illustrating examples of technical terms used for defining two functions f(σ) and g(σ);

FIG. 9 is a diagram illustrating a sweep algorithm in operation of narrowing down a possible area range of a bridge location;

FIG. 10 is a diagram illustrating an example of a program for generating a boundary X of a chain P segmented into trapezoids, and a boundary X of a chain P to which a λ-boundary bridge is added using a fixed point λ; and

FIGS. 11A to 11B are diagram illustrating a method of updating a segment tree in the operation of narrowing down the possible area range of the bridge position.

### DETAILED DESCRIPTION OF EXEMPLARY EMBODIMENTS

In order to fully understand the present invention, operational advantages of the present invention, and objects attained by practicing the present invention, reference should be made to the accompanying drawings that illustrate embodiments of the present invention and to the description in the accompanying drawings.

Hereinafter, exemplary embodiments of the present invention will be described in detail with reference to the accompanying drawings.

The same reference numerals in each drawing indicate the same members.

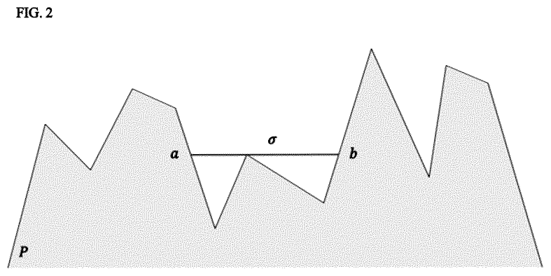

FIG. 2 shows a discrete two-dimensional polygon used in an algorithm for finding a location of a bridge on the same land according to the present invention.

Referring to FIG. 2, in the present invention, an x-monotone polygonal chain P (hereinafter, referred to as a chain P) is used as a substitute for a coastal boundary of the land.

The shading, which is indicated below the chain P expressed by a bold line, represents the land.

A sea bridge σ connects two middle points a and b of the chain P and does not pass through a lower portion of the chain P, that is, the land.

In the following description, the chain P and a coastal boundary will be used interchangeably.

The chain P is assumed to have n vertexes (n is a natural number), and when a movement is possible within an area located below a boundary of the chain P, the core idea of the present invention is to build a horizontal bridge not passing through an inside of the chain P so as to reduce a maximum Manhattan distance between two points on the chain P.

The Manhattan distance is one of methods of measuring a distance between two points in a two-dimensional plane space and may be defined as the sum of horizontal and vertical travel distances between the two points.

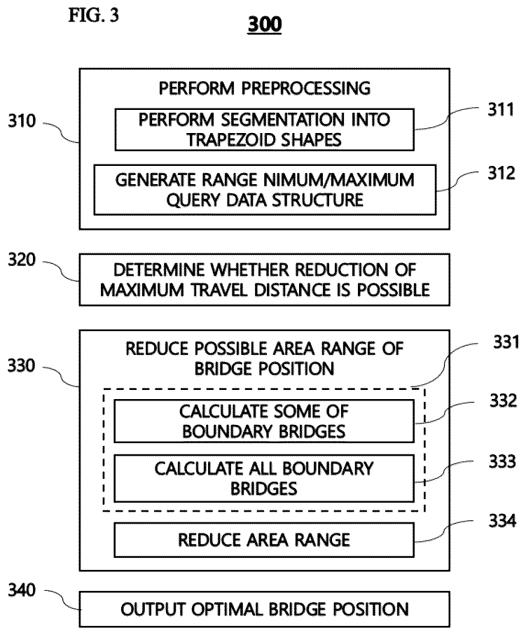

FIG. 3 shows a flowchart of a method of setting a sea bridge position according to the present invention.

Referring to FIG. 3, a method (300) of setting a sea bridge position according to the present invention includes a preprocessing operation (310), an operation of determining whether reduction of a maximum travel distance is possible (320), an operation of reducing a possible area range of a bridge position (330), and an operation of outputting an optimal bridge position (340).

The method (300) of setting a sea bridge position according to the present invention shown in FIG. 3 may be performed by a computer, a processor, signal processing device for processing input information in the preprocessing operation (310) according to a pre-stored program to generate optimal bridge position information.

The preprocessing operation (310) includes an operation of segmenting the chain P into trapezoid shapes (311) and an operation of generating a range minimum/maximum query data structure (312).

The operation of segmenting the chain P into the trapezoid shapes (311) segments a given coastal boundary, i.e., the chain P, into trapezoid shapes using horizontal line segments.

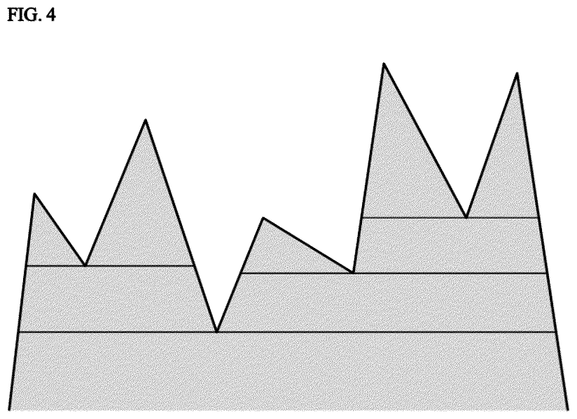

FIG. 4 shows the operation of segmenting the chain P into the trapezoid shapes (311).

Referring to FIG. 4, when the trapezoid shapes are generated, a horizontal line segment has a length in which one end starts from a point on the boundary of the chain P and proceeds horizontally into the chain P until an opposite end reaches a point on the boundary of the chain P.

The operation of generating the range minimum/maximum query data structure (312) generates, at O(n) time, a data structure capable of generating points p, which are maximum/minimum values of x(p)+y(p), x(p)−y(p), and y(p) n some portions of the boundary of the chain P during O(1) time.

Here, x and y denote coordinates of FIG. 4 in horizontal and vertical directions, respectively.

In order to describe an execution time of the method (300) of setting a sea bridge position according to the present invention, an inverse Ackermann time as in mathematical expression 1 is introduced.

$$O ( α ( n ) ) \qquad [ Mathematical Expression 1 ]$$

Mathematical expression 1 is an inverse Ackermann time which means a time per operation using disjoint sets.

The operation of determining whether the reduction of the maximum travel distance is possible (320) determines whether the reduction of the maximum travel distance on the land is possible by building a bridge on a given coastal boundary, i.e., the boundary of the chain P.

When a bridge capable of reducing the maximum travel distance is assumed as a useful bridge, the existence of the useful bridge means that there is a common reflex vertex through which all paths with the maximum travel distance pass, and the reflex vertex is assumed as an anchor.

Here, the reflex vertex means a vertex located below the chain P.

In order to determine the presence or absence of an anchor and to find the anchor, a maximum travel path, which is a path with the maximum travel distance passing through each concave vertex of the chain P is found.

This may be calculated in O(1) time using the range minimum/maximum query data structure.

Travel paths on the land between arbitrary two points forming a pair, that is, two points located on the boundary of the chain P, may be diverse, and lengths of travel paths may also be different.

The maximum travel path between the arbitrary two points may be the path with the maximum travel distance among a plurality of paths between the arbitrary two points, and one of the reflex vertexes via the paths through which the maximum travel path passes may be a candidate to become the anchor.

For a maximum travel path between the arbitrary two points separated from the two arbitrary points, a reflex vertex that is a candidate of the anchor may be calculated.

In addition to the four points described above, it is possible to add an additional pair of two points when necessary and calculate reflex vertexes that are candidates for the anchor.

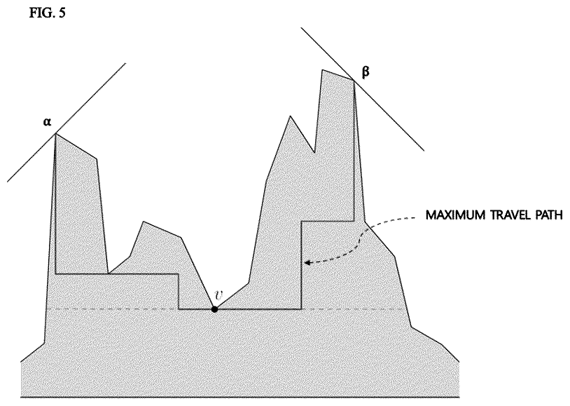

FIG. 5 shows a relationship between a concave vertex and the anchor of the chain P.

Referring to FIG. 5, a reflex vertex v included in the maximum travel path between two points a and B of the chain P may become an anchor of the maximum travel path.

When there is only one reflex vertex included in the maximum travel path between the two arbitrary points, the vertex becomes the anchor, but when there is on one reflex vertex, no useful bridge may be concluded.

In this case, all useful bridges should contain anchors between two end points of the useful bridges based on an x-coordinate.

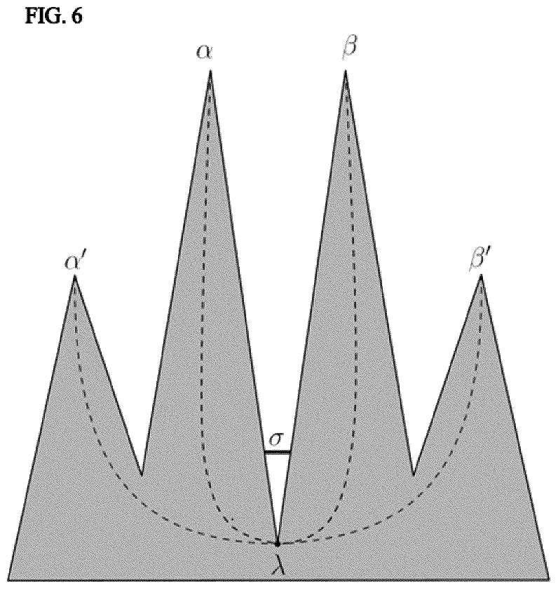

FIG. 6 shows a maximum travel path and an anchor when a bridge capable of reducing a maximum travel distance is present.

Referring to FIG. 6, it can be seen that two maximum movement paths between two points (α:β, α′:β′) corresponding to each other share one reflex vertex, i.e., a fixed point λ.

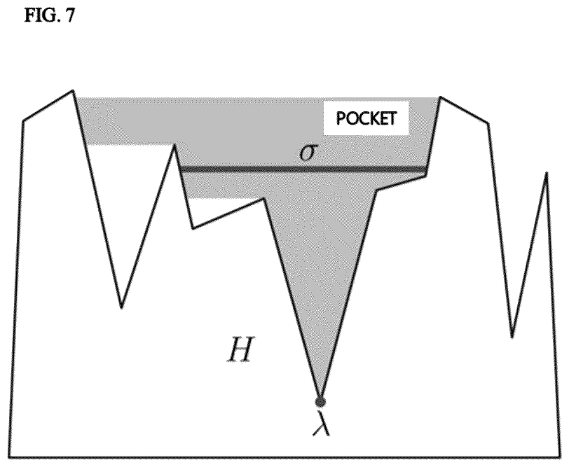

FIG. 7 shows an example of a pocket.

Referring to FIG. 7, an area where the useful bridge can be located is assumed as a pocket.

In the operation of determining whether the reduction of the maximum travel distance is possible (320), when it is determined that the useful bridge is present, it is desirable to perform the operation of reducing the possible area range of the bridge position (330) which will be described below. However, when it is determined that the useful bridge is not present, a bridge may be installed on the basis of a separate premise instead of the present invention.

The operation of reducing the possible area range of the bridge position (330) includes an operation of calculating candidate bridges to be used in a binary search (331) and an operation of reducing an area range (334) which narrow down an area where an optimal bridge can be placed within the pocket through a binary search, compare and determine two functions f(σ) and g(σ) for the maximum travel distance which is determined according to whether the optimal bridge is present above or below a bridge σ inside the pocket.

The operation of calculating the candidate bridges to be used in the binary search (331) includes an operation of calculating some of boundary bridges (332) and an operation of calculating all the boundary bridges (333).

In order to help technical understanding of the processing operations which will be described below, two functions f(σ) and g(σ) are defined first.

For arbitrary two sets A and B, {p|p∈A and p∉(B} is defined as A\B, and {(p,q)|p∈A, q∈B} is defined as A×B.

That is, A\B means arbitrary point p that belongs to set A but not to set B, and A×B means arbitrary two points p and q belonging to set A and set B, respectively.

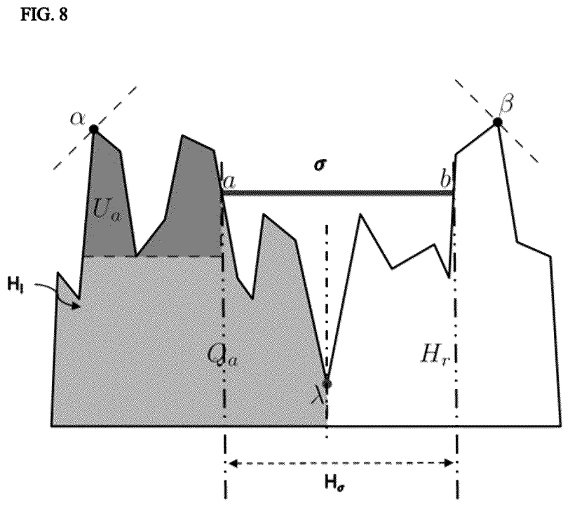

FIG. 8 shows examples of technical terms used for defining two functions f(σ) and g(σ).

Referring to FIG. 8, two end points of the bridge σ are assumed as a and b, and the boundary of the chain P is separated by a vertical line (an alternated long and short dash line) passing through a fixed point λ, and a left boundary is assumed as Hₗ and a right boundary is assumed as Hᵣ. Here, the bridge σ is a reference bridge arbitrarily defined in the chain P, and an optimal bridge determined according to the present invention may be determined using the reference bridge.

A point at which x(p)−y(p) is minimum in Hₗ may be obtained in time O(1) through the range minimum/maximum query data structure of the preprocessing operation (310), this point p is assumed as α.

An area, which represents the points p satisfying that a point with the smallest y-coordinate among paths from arbitrary point p to a included in the chain P is greater than or equal to a point with the smallest y-coordinate among paths from α to a, becomes Uₐ.

Qₐ is defined as Hₗ\Uₐ. Since Qₐ belongs to Hₗ but does not belong to Uₐ, in FIG. 8, Qₐ may be an area excluding Uₐ from Hₗ.

Similarly, a point β where x(p)+y(p) is maximum at Hᵣ may be obtained in time O(1), and U_{b} may be defined using β and b.

Q_{b} is defined as Hᵣ\U_{b}. Q_{b} may be defined in the same manner as Qₐ.

An area between two straight lines (dash lines) extending perpendicularly from each of two endpoints a and b of σ is referred to as H_{σ}.

f(σ) is defined as the maximum travel distance in an area where σ is installed on the boundary of the chain P belonging to Qₐ×Q_{b} or {(p,q)|p∈H_{σ},q∈σ}.

g(σ) is defined as the maximum travel distance in the area where σ is installed on the boundary of the chain P belonging to Hₗ×Hₗ, Uₐ×Hᵣ, Hᵣ×Hᵣ, or U_{b}×Hₗ.

For the two points a and b on the chain P, the boundary of the chain P placed between a and b is denoted as P[a,b] and for a given bridge σ=ab, P[a,b] is denoted as P[σ].

When two bridges σ₁ and σ₂ are installable on the chain P, f(σ₁)≤f(σ₂) is satisfied when P[σ₁]⊆P[σ₂] is satisfied.

A process of calculating g(σ) will be described on the basis of the technical terms defined above.

For areas and Hₗ×Hₗ and Hᵣ×Hᵣ, g(σ) may be calculated by finding a maximum travel distance inside Hₗ and Hᵣ.

g(σ) for area Uₐ×Hᵣ may be calculated by finding a maximum travel distance from α to Hᵣ. Among points included in Hᵣ, when an area of points, where the shortest path from α to a corresponding point includes σ, is referred to as A, and when an area of points, where the shortest path from α to a corresponding point does not include σ is referred to as B, the area A and the area B may be calculated in time O(log n) using a binary search.

Since the maximum travel distance g(σ) from the area A of the points where the shortest path σ from α to the corresponding point should include b, the maximum travel distance may be calculated by finding the farthest point at a in the corresponding area from b. A method of maintaining a data structure that finds the farthest point from a portion of the boundary of the chain P to b in time O(log n) will be described in a description of the operation of calculating all the boundary bridges (333).

Since the maximum travel distance g(σ) from a to the area B of points where the shortest path does not include σ should pass through the fixed point λ, a distance from the fixed point λ to the farthest point may be found in time O(1) using the range minimum/maximum query data structure.

Area U_{b}×Hₗ may be calculated in the same manner of calculating g(σ) for area U_{σ}×Hᵣ, and g(σ) may be calculated in time O(log n).

Next, a process of calculating f(σ) will be described.

A maximum distance from each vertex of Qₐ to Q_{b} is calculated using σ in the same manner when g(σ) is calculated and, after a closer area and a lesser area are calculated, the maximum travel distance f(σ) is calculated using the range minimum/maximum query data structure generated in the preprocessing operation (310).

When a process of calculating the closer area is performed in regular order along a boundary of a Qₐ using σ for each vertex, areas for all vertexes may be calculated in time O(n) After the closer area is calculated using σ at the vertex of Qₐ, a maximum travel distance from the vertex may be found in time O(1) through the range minimum/maximum query data structure. It is possible to calculate maximum travel distances at all vertexes of Qₐ in time O(n).

It is possible to calculate the maximum travel distances from all vertexes of Q_{b} to Qₐ in time O(1) Among pairs (p, q) of points included in {(p,q)|p∈H_{σ},q∈σ}, a pair (p, q) of a point having the maximum movement distance may be calculated by calculating a maximum distance from each vertex of H_{σ} to σ, and the calculation for all vertexes is possible in time O(n). Therefore, f(σ) may be calculated in time O(n).

It is previously described that the operation of reducing the possible area range of the bridge position (330) includes the operation of calculating the candidate bridges to be used in the binary search (331) and the operation of reducing the area range (334), and the operation of calculating the candidate bridges to be used in the binary search (331) includes the operation of calculating some of the boundary bridges (332) and the operation of calculating all the boundary bridges (333).

In the operation of calculating some of the boundary bridges (332), P(σ) includes the fixed point λ, and one of two end points of σ is obtained by calculating all bridges, which become vertexes of a trapezoidal segmentation calculated in the preprocessing operation (310), from λ in regular order.

These bridges are assumed as “λ-boundary bridges (critical shortcuts).”

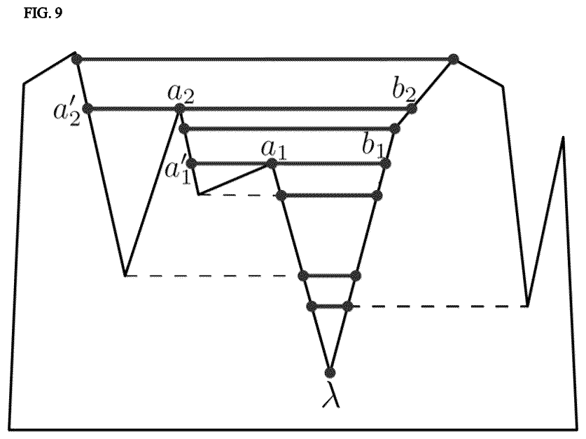

FIG. 9 is a diagram illustrating a sweep algorithm in operation of narrowing down a possible area range of a bridge location.

A plurality of horizontal line segments connecting two circles are bridges with vertexes calculated in the operation of segmenting the chain P into the trapezoid shapes (311) of the preprocessing operation (310) as end points and represent the result of applying a sweep algorithm starting from the fixed point λ.

In FIG. 9, the longest horizontal line segment that is outside a boundary of a given point P and includes a given point p is referred to as a maximum horizontal line segment.

When the given point p is not an end point of its own maximum horizontal line segment, the point p is referred to as a peak.

When the end point of the bridge is a peak, the end point of the bridge is extended and the line segment is extended until it meets the boundary of the chain P, and a̅′̅₁̅b̅₁̅ and a̅′̅₂̅b̅₂̅ include extended line segments a1-a1′ and a2-a2′.

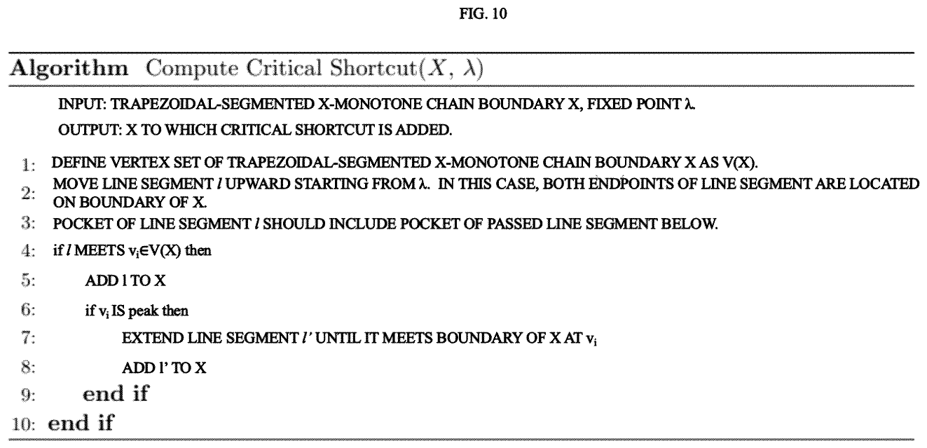

FIG. 10 is an example of a program for generating a boundary X of a chain P segmented into trapezoids, and a boundary X of a chain P to which a λ-boundary bridge is added using the fixed point λ.

Referring to FIG. 10, the purpose of calculating the λ-boundary bridge (critical shortcut) is to make the function g(σ) maintain monotonicity and continuity within a section segmented by the line segment. Since the monotonicity of g(σ) within each section cannot be secured with only the operation of calculating some of the boundary bridges (332), it is proposed to perform the operation of calculating all the boundary bridges (333), which will be described below.

The operation of calculating all the boundary bridges (333) sequentially calculates g(σ) values of the λ-boundary bridges from the fixed point λ in an upward direction and adds new λ-boundary bridges between the existing λ-boundary bridges to secure monotonicity of g(σ).

In the process of calculating g(σ) for all the λ-boundary bridges, a data structure utilizing a segment tree is constituted so as to calculate max_{p∈P[t,u]}d_{σ}(a,p) and max_{p∈P[t,a]}d_{σ}(b,p) in time O(log n). This process can be easily understood by referring to the above-described non-patent document that is the related art document.

The data structure utilizing the segment tree maintains a distance {d₁, . . . dₘ}={d(p₁,b), . . . , d(pₘ,b)} to b for all vertexes p₁, . . . , pₘ in the chain P. In addition, when a bridge appearing next to σ is referred to as σ=a′b′ in the sweep algorithm, y(b′)<y(pₖ) is satisfied, and a path from b′ to pₖ maintains an index section I in which k=1 . . . , m that is an xy-monotonic path is collected.

When the sweep algorithm starts, I is initialized by finding b and a boundary edge of the chain P, which includes the rightmost point among points intersecting the boundary of the chain P, by extending b, and then d₁, . . . dₘ is directly calculated.

Thereafter, d₁, . . . dₘ is updated by cases into a case in which bb′ belongs to the boundary edge of the chain P and a case in which bb′ does not belong to the boundary edge of the chain P. In the case in which bb′ belongs to the boundary edge of the chain P, when updating from d(p₁,b), . . . , d(pₘ,b) to d(p₁,b′), . . . , d(pₘ,b′) is performed, all ks that is k∈l are each subtracted by d(b,b′) and other ks are each added by (x(b)−x(b′))+(y(b′)−y(b′).

When bb′ does not belong to the boundary edge of the chain P, updating of I uses a line segment of a trapezoidal segment including b′.

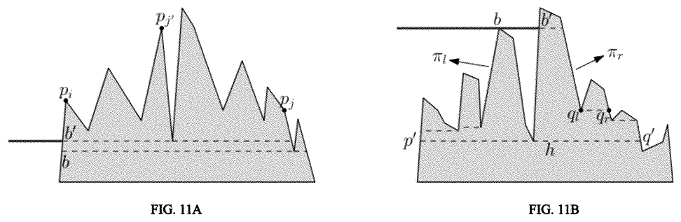

FIGS. 11A to 11B shows a method of updating a segment tree in the operation of narrowing down the possible area range of the bridge position.

When right points of the two endpoints of σ and σ′, which are candidates for a bridge, are b and b′, respectively, FIG. 11A shows the case in which bb′ belongs to the boundary edge of the chain P, and FIG. 11B shows the case in which bb′ does not belong to the boundary edge of the chain P.

In FIGS. 11A to 11B, when the longest horizontal line segment, among horizontal line segments which are present outside the boundary of the chain P and each include a given point p, is referred to as a maximum horizontal line segment, and when the given point p is not an endpoint of its own maximum horizontal line segment, the point is referred to as a peak and pⱼ becomes the peak in FIG. 11A.

Referring to FIG. 11B, it can be seen that, when an endpoint b of the bridge is a peak, the line segment is extended to b′ until the line segment meets the boundary.

A process of adding a λ-boundary bridge is as follows.

When g(σ) does not maintain monotonicity between any two λ-boundary bridges sᵢ and sᵢ₊₁ added sequentially by the sweep algorithm, among arbitrary bridges, a bridge s* in which g(σ) decreases between sᵢ and sᵢ₊₁ and g(σ) monotonically increases between s* and sᵢ₊₁ is found.

A detailed description thereof is as follows.

dₛ(p,q) denotes a distance between two points p and q of the chain P when a bridge s is added for the two points p and q. When g(σ) decreases, g(σ) becomes d_{σ}(α,β) and does not present except for the case in which d_{σ}(α,β) decreases.

The case in which d_{σ}(α,β) decreases is only possible when both a path from α to aᵢ₊₁ and a path from β to bᵢ₊₁ are monotone. In that case, sᵢ<s*<sᵢ₊₁ in which d_{σ}(α,β) and max_{q∈Q}_{ᵣ}dₛ(α,q) are equal is calculated to allow g(σ) to decrease between sᵢ and s* and allow g(σ) to monotonically increase between s* and sᵢ₊₁.

Since Qᵣ consists of P[λ,b] and P[u_{σ},pᵣ], in order to calculate max_{q∈Q}_{ᵣ}dₛ(α,q), a maximum distance is calculated for P[λ,b] and P[u_{σ},pᵣ] from α. Therefore, in order to calculate s*, s₁* satisfying dₛ_{₁}_{*}(α,β)=max_{q∈P[λ,b]}dₛ_{₁}_{*}(α,q) s₂* and satisfying dₛ_{₂}_{*}(α,β)=max_{q∈P[u}_{_{σ}}_{,p}_{ᵣ}_{]}dₛ_{₂}_{*}(α,q) are calculated and, when s₁*<s₂* is satisfied, s₁* is set and, otherwise, s₂* is set.

s₁* satisfying dₛ_{₁}_{*}(α,β)=max_{q∈[λ,b]}dₛ_{₁}_{*}(α,q) may be calculated in time O(log n) using a binary search. Similarly, s₂* may also be calculated in time O(log n).

The operation of reducing the area range (334) finds two λ-boundary bridges sᵢ and sᵢ₊₁ to find an area where an optimal bridge may be located.

For a given line segment sᵢ, a distance function with a minimum value of g(s) within a range of sᵢ or below is defined as g*(sᵢ). Since g*(s) monotonically decreases and f(s) monotonically increases, an index I satisfying f(sᵢ)≤g*(sᵢ) and f(sᵢ₊₁)≥g*(sᵢ₊₁) may be found through a binary search.

The calculation of f(s) is required for time O(n), and since O(log n) calculations are required when the binary search is performed, time O(n log n) is required to find a corresponding the index i.

In order to narrow down the possible area range of the bridge position, the operation of outputting the optimal bridge position (340) calculates the optimal bridge position by performing the binary search on the candidate areas calculated in the operation of reducing the possible area range of the bridge position (330).

In order to find the optimal bridge location, among the bridges between sᵢ and sᵢ₊₁, a and bridge sₚ satisfying g(sₚ)=max_{q∈Q}_{_{b}}dₛ_{ₚ}(p,q) for a vertex p of Qₐ and a bridge s_{q} satisfying g(s_{q})=max_{q∈Q}_{ₐ}dₛ_{ₚ}(p,q) for a vertex q of Q_{b} are calculated. Among these sₚ and s_{q}, the bridge s* with the smallest y-coordinate value satisfies f(s*)=g(s*) and becomes the optimal bridge position.

FIGS. 11A to 11B show the method of updating a segment tree in the operation of narrowing down the possible area range of the bridge position.

When right points of the two endpoints σ and σ, that are the candidate bridges are referred to as b1 and b2, respectively, FIG. 11A shows a case in which b1 and b2 belong to the boundary edges of the chain P, and FIG. 11B shows a case in which b1 belongs to the peak of the chain P and b2 belongs to the boundary edge of the chain P.

In FIGS. 11A to 11B, when the longest horizontal line segment, among horizontal line segments which are present outside the boundary of the chain P and each include a given point p, is referred to as a maximum horizontal line segment, and when the given point p is not an endpoint of its own maximum horizontal line segment, the point is referred to as a peak and pⱼ becomes the peak in FIG. 11A.

Referring to FIG. 11B, it can be seen that, when the endpoint b of the bridge is the peak, the line segment is extended to b′ until the line segment meets the boundary.

As described above, according to a method of setting a sea bridge position according to the present invention, a technology, which has never been proposed or disclosed in any previous solution, has an advantage of minimizing a travel distance on the land between two places by installing a sea bridge crossing the sea between the two places on the land in a straight line.

The effects obtained by the present invention are not limited to the above-described effects and other effects which are not described can be clearly understood by those skilled in the art to which the present invention pertains from the following description.

Although the technical spirit of the present invention has been described above with reference to the accompanying drawings, this describes only exemplary embodiments of the present invention and does not limit the present invention.

In addition, it is obvious that those skilled in the art in the technical field to which the present invention pertains can make various modifications and imitations without departing from the scope of the technical spirit of the present invention.

What is claimed is:

1. A method of setting a sea bridge position, comprising:
preprocessing of segmenting an x-monotonic polygon chain (hereinafter, referred to as a polygonal chain) corresponding to a given coastal boundary into trapezoids using horizontal line segments and generating a range minimum/maximum query data structure;
determining whether a maximum travel distance on the land is reduced by constructing a bridge on the polygonal chain by determining whether a useful bridge capable of reducing the maximum travel distance is present; and
narrowing down an area where the useful bridge is placed through a binary search inside a pocket which is an area where the useful bridge is located, and reducing a possible area range of a bridge position by comparing a first maximum travel distance and a second maximum travel distance, which are determined on the basis of whether an optimal bridge is located above or below a reference bridge inside the pocket.

2. The method of claim 1, wherein the preprocessing includes:
segmenting the polygonal chain into a trapezoidal shape; and
generating a range minimum/maximum query data structure related to a specific point in a portion of the polygon chain.

3. The method of claim 2, wherein the range minimum/maximum query data structure includes the sum and difference of x-coordinate and y-coordinate values of the specific point and minimum and maximum values of the y-coordinate values of the specific point.

4. The method of claim 1, wherein the determining of whether the maximum travel distance is reduced includes:
determining whether a common reflex vertex (hereinafter referred to as an anchor) through which all paths with the maximum travel distance at arbitrary two points included in the polygonal chain pass are present; and
in order to calculate the anchor, finding the maximum travel path passing through reflex vertexes of the polygon chain using the range minimum/maximum query data structure.

5. The method of claim 4, wherein the determining of whether the maximum travel distance is reduced further includes:
when only a concave vertex is included in the maximum travel path between arbitrary two points of the polygonal chain, determining that the useful bridge is present; and
when only the concave vertex is not included in the maximum travel path between the arbitrary two points of the polygonal chain, determining that the useful bridge is not present.

6. The method of claim 4, wherein the reducing of the possible area range of the bridge position includes:
generating λ-boundary bridges in regular order from the anchor in an upward direction by applying a sweep algorithm; and
adding the generated λ-boundary bridges to a boundary of the polygonal chain.

7. The method of claim 1, wherein the reducing of the possible area range of the bridge position includes:
calculating candidates of a bridge to be used in a binary search using two functions; and
reducing an area where the bridge is located.

8. The method of claim 7, wherein the calculating of the candidates of the bridge to be used in the binary search includes:
sequentially calculating a λ-boundary bridge (critical shortcut), which allows one of two endpoints of the bridge to become a vertex of the trapezoid segment calculated in the preprocessing, from the anchor, wherein a bridge to be installed includes the anchor; and
sequentially calculating the first maximum travel distance of the λ-boundary bridge in an upward direction from the anchor, and calculating all boundary bridges, which adds a new λ-boundary bridge between the existing λ-boundary bridges.

9. The method of claim 8, wherein the calculating of the candidates of the bridge to be used in the binary search further includes:
finding λ-boundary bridges at two arbitrary adjacent points; and
reducing a range area for finding a candidate bridge at a point having characteristics in which the second maximum travel distance at one of the two arbitrary adjacent points is greater than a distance function having a minimum value of the first maximum travel distance within a range that is less than or equal to the one point, and that the second maximum travel distance at the other one of the two arbitrary adjacent points is less than a distance function having a minimum value of the first maximum travel distance at the other one of the two arbitrary adjacent points within a range that less than or equal to the one point.

10. The method of claim 9, further comprising:
performing the binary search on the candidate bridges, calculating a position of the optimal bridge, and determining and outputting the optimal bridge.
